(19) United States
(12) Patent Application Publication
(10) Pub. No.: US 2010/0208575 A1
(43) Pub. Date: Aug. 19, 2010

(54) METHOD AND APPARATUS FOR SHOCK AND ROTATIONAL VIBRATION SENSING IN A HARD DISK DRIVE

(76) Inventor: Brian K. Tanner, San Jose, CA (US)

Correspondence Address: GSS Law Group, 3900 Newpark Mall Road, Newark, CA, 94560, US

(21) Appl. No.: 12/389,112

(22) Filed: Feb. 19, 2009

(51) Int. Cl. G11B 23/00; H01L 41/113; G01P 15/09

(52) U.S. Cl. 369/263.1; 310/329; 73/514.34; G9B/23

(57) ABSTRACT

A hard disk drive and its circuit board are disclosed using just two piezoelectric devices to estimate both shock events and rotational vibration instead of the three devices required by the prior art. Also disclosed, an integrated circuit coupling to these two piezoelectric devices generates the signals associated with shock events and rotational vibration and a processor that may use these signals to direct the operations of the hard disk drive and may configure the components of the integrated circuit. The integrated circuit may or may not include the processor.

### TECHNICAL FIELD

This invention relates to the sensing of external mechanical shock and rotational vibrations in a hard disk drive.

### BACKGROUND OF THE INVENTION

Hard disk drives, particularly when used in portable applications such as notebook computers and portable media players are subject to mechanical shocks. Rotational vibrations can directly and significantly affect the quality of slider positioning. One standard approach to addressing these issues is to use one piezoelectric device to determine shock events and two additional piezoelectric devices to determine the rotational vibration acting on the hard disk drive. However, not all applications can afford to buy hard disk drives with all these piezoelectric devices, and even when the application can afford it, there is a competitive advantage to providing these measurements and determinations for less cost.

### SUMMARY OF THE INVENTION

Embodiments of the invention include a hard disk drive with a piezoelectric component group consisting of two piezoelectric devices, the first mounted in the plane of the disk base and the second mounted at an angle Phi from the plane of the disk base. One or both of the two piezoelectric devices may be mounted on the disk base and/or mounted on a circuit board, configured to be mounted on the disk base opposite the disks. The circuit board may further include an integrated circuit electrically coupled to the piezoelectric devices to generate three signals, a shock event signal, a rotational compensation signal and a rotational event signal that are provided to a processor. The processor may direct the voice coil motor mounted through a pivot to the disk base to position at least one slider over at least one rotating disk surface to access data in a track on the rotating disk surface based upon these signals.

The processor may be included in the integrated circuit or may be part of another component of the circuit board. The processor may configure the components of the integrated circuit through control of the gain of amplifiers and the control of high and low thresholds of threshold comparators used to generate the shock event signal, the rotational compensation signal and the rotational event signal. The operations performed by the hard disk drive may be implemented as program steps in a program system residing in a computer readable memory that may be configured for access by a computer or to implement a finite state machine, possibly as a Field Programmable Gate Array (FPGA).

### BRIEF DESCRIPTION OF THE DRAWINGS

FIG. 1 shows an example embodiment of a hard disk drive that includes a disk base with a spindle motor mounted on it and coupled to at least one disk to create a rotating disk surface. A voice coil motor is mounted on the disk base with its head stack assembly coupling through an actuator pivot to position at least one slider near a track on at least one of the rotating disk surfaces. Communications between the slider and other components of the head stack assembly are sent via an interface to a circuit board mounted on the opposite side of the disk base from the disks and voice coil motor. A disk cover is mounted on the disk base to enclose the disks, spindle motor and voice coil motor.

FIG. 2 shows an example of the opposite side of the disk base with the interface to the head stack assembly typical of a three and one half inch hard disk drive.

FIG. 3 shows a prior art example of a circuit board for the disk base of FIG. 2 with three piezoelectric devices, two of the piezoelectric devices mounted parallel the disk base for use in rotational vibration sensing and one mounted at an angle Phi from the plane of the disk base.

FIG. 4 shows an example of a circuit board for the disk base of FIG. 2 with just two piezoelectric devices for doing the tasks previously performed by the three piezoelectric devices of FIG. 3, one mounted parallel to the disk base and the other mounted at an angle Phi from the plane of the disk base.

FIG. 5 shows a prior art example of the circuit board that may be used in a two and one half inch hard disk drive with three piezoelectric devices, two of the piezoelectric devices mounted parallel the disk base for use in rotational vibration sensing and one mounted at an angle Phi from the plane of the disk base.

FIG. 6 and 7 shows examples of circuit boards with just two piezoelectric devices for doing the tasks previously performed by the three piezoelectric devices of FIG. 5, one mounted parallel the disk base and the other mounted at an angle Phi from the plane of the disk base. FIG. 6 shows a configuration that may be more accurate at rotational vibration sensing. FIG. 7 shows a configuration that may be more accurate at mechanical shock sensing. Both of these examples may be good enough for production. Both Figures show an integrated circuit that may be coupled to these piezoelectric devices to generate the signals based upon these piezoelectric devices in accord with the invention.

FIG. 8 shows a simplified schematic of the integrated circuit electrically coupled to the first and second piezoelectric devices of FIGS. 4, 6 and 7 to generate three signals, a shock event signal, a rotational compensation signal and a rotational event signal that are provided to a processor, which may or may not be included in the integrated circuit.

FIG. 9 shows a schematic of some further details of the hard disk drive with the processor directing the voice coil motor to position at least one slider over at least one rotating disk surface to access data in a track on the rotating disk surface based upon these signals. The processor may also direct the spindle motor in its process of rotating the disks to create the rotating disk surfaces.

FIG. 10 shows a simplified control feedback diagram of the rotational compensation signal being used with a Position Error Signal (PES) to generate a Voice Coil Motor (VCM) current to direct the voice coil motor in its positioning of the slider over the track on the rotating disk surface.

FIG. 11 shows a simplified schematic of an implementation of the processor that may include at least one instance of a finite state machine and/or at least one instance of a computer accessibly coupled via a buss to a computer readable memory containing a program system. The various configuration parameters of the components of the integrated circuit shown in FIG. 8 may be initialized or altered by the processor.

FIG. 12 shows a flowchart of the program system of FIG. 11 including at least one of program steps configuring the amplifiers and threshold comparators, estimating the shock event signal, the rotational compensation signal and/or the rotational event signal, using the rotational compensation signal and Position Error Signal to create the voice coil motor current and suspending write operations in response to the shock event signal being asserted.

And FIG. 13 shows a flowchart of some of the details of the program step using the rotational compensation signal and Position Error Signal to create the voice coil motor current.

### DETAILED DESCRIPTION

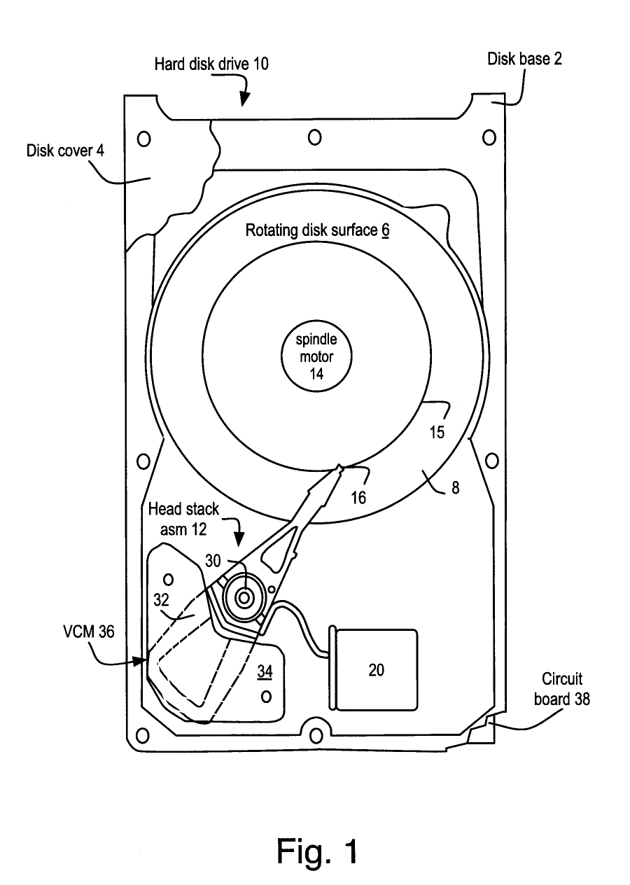

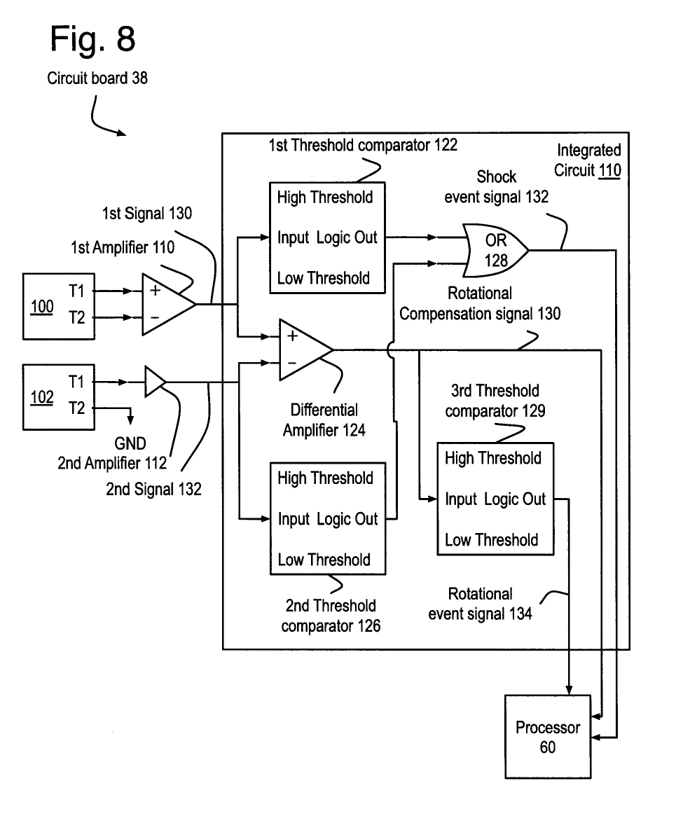

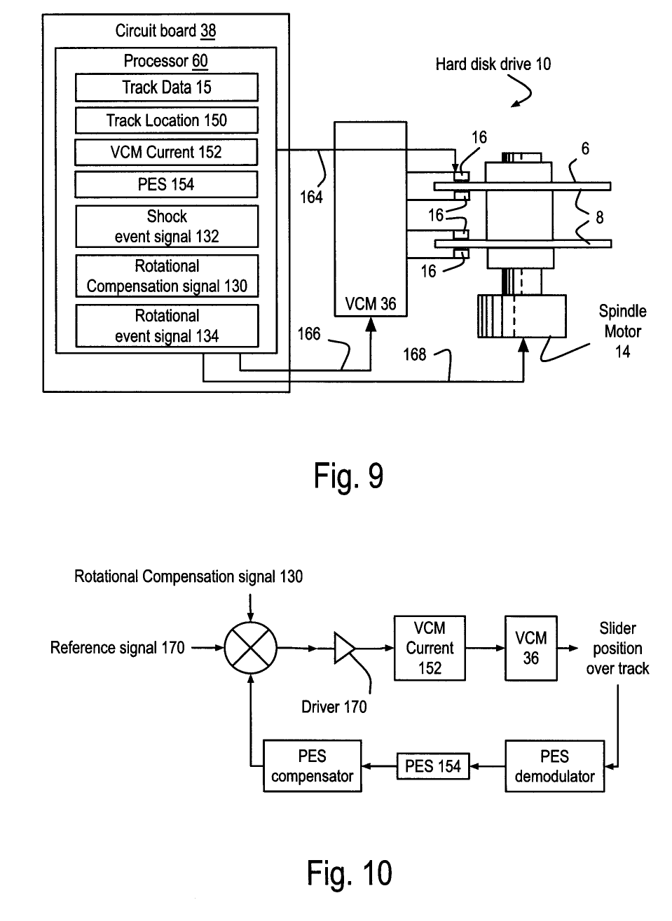

This invention relates to the sensing of external mechanical shock and rotational vibrations in a hard disk drive. Embodiments of the invention include a hard disk drive as shown in FIGS. 1 and 2 with a piezoelectric component group consisting of two piezoelectric devices, the first mounted in the plane of the disk base and the second mounted at an angle Phi from the plane of the disk base as shown in FIGS. 4, 6 and 7. One or both of the two piezoelectric devices may be mounted on the disk base and/or mounted on a circuit board, configured to be mounted on the disk base opposite the disks. FIG. 8 shows the circuit board may further include an integrated circuit electrically coupled to the piezoelectric devices to generate three signals, a shock event signal, a rotational compensation signal and a rotational event signal that are provided to a processor. FIG. 9 shows the processor may direct the voice coil motor to position at least one slider over at least one rotating disk surface to access data in a track on the rotating disk surface based upon these signals. FIGS. 10 to 13 show further details of the operations of the hard disk drive, these piezoelectric devices, the integrated circuit and the processor.

Referring to the drawings more particularly by reference numbers, FIG. 1 shows an example embodiment of a hard disk drive 10 that includes a disk base 2 with a spindle motor 14 mounted on it and coupled to at least one disk 8 to create a rotating disk surface 6. A voice coil motor 36 is mounted on the disk base with its head stack assembly 12 coupling through an actuator pivot 30 to position at least one slider 16 near a track 15 on at least one of the rotating disk surfaces. The voice coil motor pivots about the actuator pivot, moving in response to electrical stimulus of the voice coil 32 and its interaction with a fixed magnet assembly 34. Communications between the slider and other components of the head stack assembly are sent via an interface 20 to a circuit board 38 mounted on the opposite side of the disk base from the disks and voice coil motor. A disk cover 4 is mounted on the disk base to enclose the disks, spindle motor and voice coil motor.

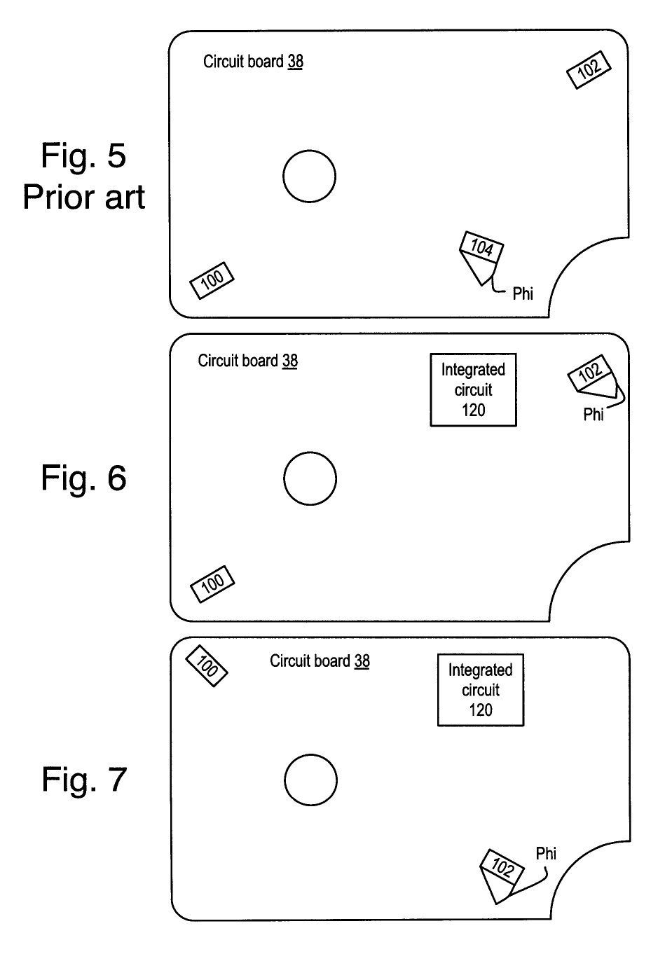

While hard disk drives 10 may be manufactured in a variety of form factors, to simplify the discussion, implementation examples will focus on two form factors. FIGS. 2, 3 and 4 show examples applicable to a three and a half inch hard disk drive. And FIGS. 5, 6 and 7 show examples applicable to a two and a half inch hard disk drive. Subsequent Figures focus on the electrical, control and operational features of the invention, and may be applicable to any hard disk drive embodying the invention.

FIG. 2 shows an example of the opposite side of the disk base 2 with the interface 20 to the head stack assembly typical of a three and one half inch hard disk drive 10.

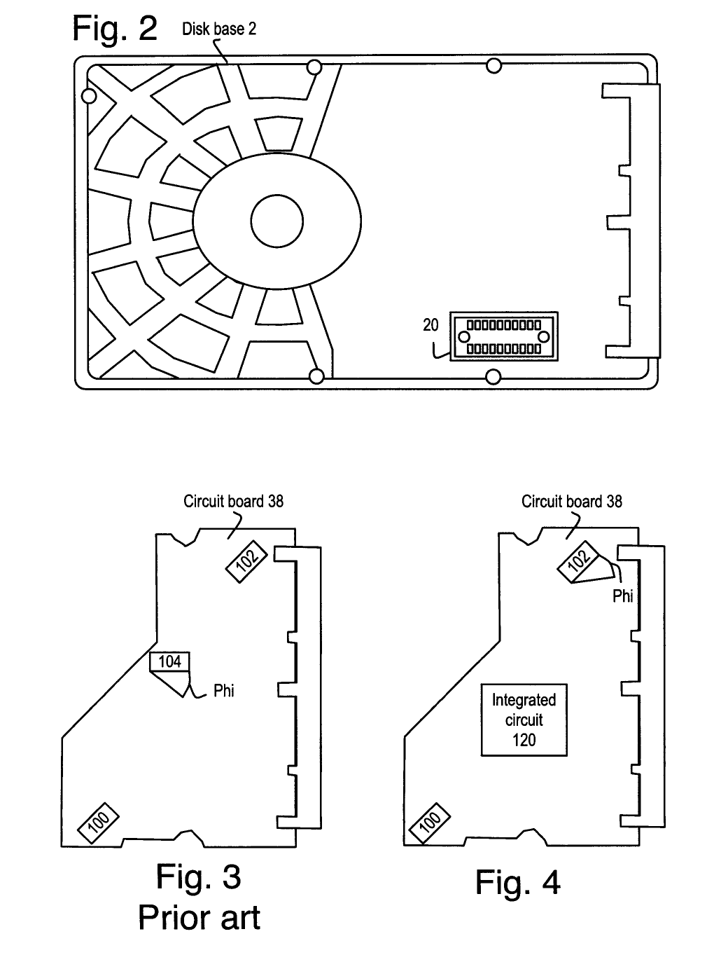

FIG. 3 shows a prior art example of a circuit board 38 for the disk base 2 of FIG. 2 with three piezoelectric devices, two of the piezoelectric devices 100 and 102 mounted parallel the disk base for use in rotational vibration sensing and one piezoelectric device 104 mounted at an angle Phi from the plane of the disk base.

FIG. 4 shows an example of a circuit board for the disk base of FIG. 2 with just two piezoelectric devices for doing the tasks previously performed by the three piezoelectric devices of FIG. 3, a first piezoelectric device 100 mounted parallel to the disk base and the second piezoelectric device 102 mounted at an angle Phi from the plane of the disk base. Various embodiments may use differing angle Phi values, which may range from at least ten degrees to at most ninety degrees. Further, the angle Phi may be between twenty degrees and thirty degrees.

FIG. 5 shows a prior art example of the circuit board 38 that may be used in a two and one half inch hard disk drive 10 with three piezoelectric devices, two of the piezoelectric devices 100 and 102 mounted parallel the disk base for use in rotational vibration sensing and one piezoelectric device 104 mounted at an angle Phi from the plane of the disk base.

FIG. 6 and 7 shows examples of circuit boards 38 with just two piezoelectric devices for doing the tasks previously performed by the three piezoelectric devices of FIG. 5, a first piezoelectric device 100 mounted parallel the disk base 2 and the second piezoelectric device 102 mounted at an angle Phi from the plane of the disk base. FIG. 6 shows a configuration that may be more accurate at rotational vibration sensing. FIG. 7 shows a configuration that may be more accurate at mechanical shock sensing. Both of these examples may be good enough for production. Both Figures show an integrated circuit 120 that may be coupled to these piezoelectric devices to generate the signals based upon these piezoelectric devices in accord with the invention.

The couplings between the integrated circuit 120 and these two piezoelectric devices 100 and 102 as well as the overall operation of the circuit board 38 and the hard disk drive 10 will now be discussed.

FIG. 8 shows a simplified schematic of the integrated circuit 120 electrically coupled to the first piezoelectric device 100 and the second piezoelectric device 102 of FIGS. 4, 6 and 7 to generate three signals, a shock event signal 132, a rotational compensation signal 130 and a rotational event signal 134 that are provided to a processor 60, which may or may not be included in the integrated circuit.

Both the first and second piezoelectric device are shown with two terminals, T1 and T2, which is a standard configuration in industry. The first piezoelectric device 100 has its two terminals electrically coupled to the differential inputs of a first amplifier 110 to create a first signal 130. The second piezoelectric device 102 is shown with one terminal coupled to a single input second amplifier 112 to create a second signal 132. The second terminal T2 of the second piezoelectric device is tied to a ground GND that may be shared with the second amplifier. Either piezoelectric device may be electrically coupled using either of these configurations.

The shock event signal 132 may be generated as follows: The first signal 130 is received as the input of a first threshold comparator 122 to assert a first threshold detection signal 123 in response to the first signal being outside a first high threshold and a first low threshold. The second signal 132 is received as the input of a second threshold comparator 126 to create a second threshold detection signal 125 in response to the second signal being outside a second high threshold and a second low threshold. The shock event signal is asserted in response to the threshold detection signals 123 and 125 indicating that the first signal is outside the first high threshold and the first low threshold, or that the second signal is outside the second high threshold and the second low threshold.

The threshold parameters may differ between the two threshold comparators 122 and 126 in that the piezoelectric devices differ in orientation to the disk base, the first piezoelectric device 100 being parallel to the disk base 2 and the second 102 being at an angle Phi away from the disk base.

The rotational compensation signal 130 may be generated as follows: the first signal 130 and the second signal 132 may be received as the differential inputs of a differential amplifier 124 to create the rotational compensation signal from the difference of these signals 130 and 132. As shown in FIG. 2, the second signal is subtracted from the first to create the rotational compensation signal. However, the rotational compensation signal may be created as the first signal subtracted from the second in other embodiments of the invention.

The rotational event signal 134 may be generated as follows: the rotational compensation signal 130 may be received as an input in a third threshold comparator 129 to create the rotational event signal in response to the rotational compensation signal being outside the third high threshold and the third low threshold.

The shock event signal 132, the rotational compensation signal 130 and the rotational event signal 134 are shown being received by a processor 60. This may be implemented in various ways. For example, the rotational compensation signal may be input to an analog to digital converter to create a binary representation used by digital logic in the processor. Alternatively, one or more of these signals may be selected for input to the processor. The integrated circuit 110 may include the processor in some embodiments, whereas in others, the processor may be separately housed.

In some embodiments of the invention, the rotational event signal 134 may be generated in the processor 60 by determining whether the rotational compensation signal 130 is outside the third high threshold and the third low threshold. Consequently, the rotational event signal would not need to be generated in the integrated circuit 110.

FIG. 9 shows a schematic of some further details of the hard disk drive 10 with the processor 60 coupled 166 to direct the voice coil motor 36 to position at least one slider 16 over at least one rotating disk surface 6 to access data in the track 16 on the rotating disk surface based upon the shock event signal 132, the rotational compensation signal 130 and the rotational event signal 134. The processor may be coupled 168 to direct the spindle motor 14 in the rotating of the disks 8 to create the rotating disk surfaces 6. The hard disk drive may read the track at a track location 150 using the Position Error Signal 154, which may be generated from the reading of a portion of each sector encoded with two pairs of differential signals often referred to as the A-B and C-D patterns.

The voice coil motor current 152 may be generated using the position error signal 154 and the rotational compensation signal 130.

FIG. 10 shows a simplified control feedback diagram for the hard disk drive 10 showing the rotational compensation signal 130 being used with a Position Error Signal (PES) 154 to generate a Voice Coil Motor current 152 to direct the voice coil motor 36 in its positioning of the slider 16 over the track 15 on the rotating disk surface 6. The slider position is determined through the demodulation of the PES signal, which is then received as an input to a PES compensator. PES compensation may include various filters and transformation to and then from a frequency domain in its contribution to the mixing of the reference signal 170 and the rotational compensation signal to feed the driver 170 to assert the voice coil motor current 152. The voice coil motor 36 acting in the hard disk drive 10 forms the plant component of this control feedback diagram. A mechanical shock acting on the hard disk drive alter the plant, sends a high frequency shock wave and/or impulse through the voice coil motor disrupting the slider's position over the track.

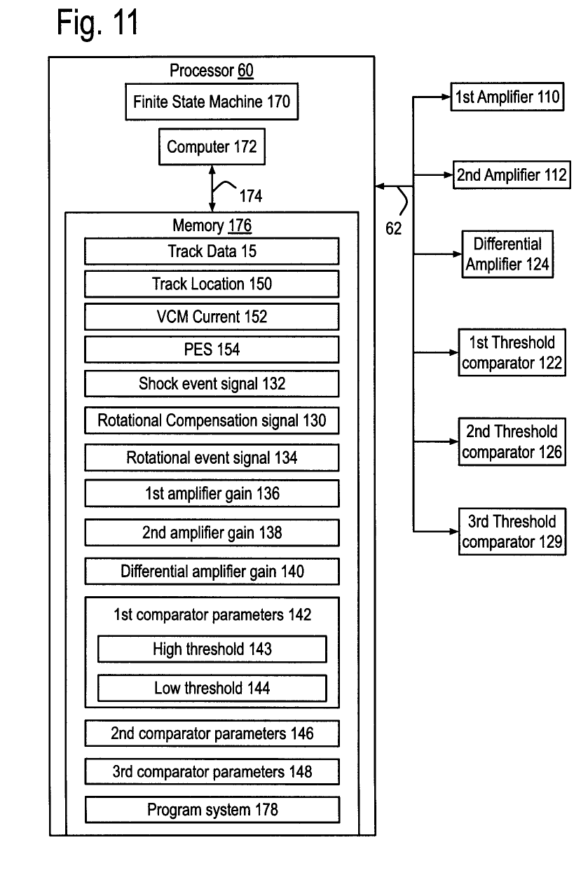

FIG. 11 shows a simplified schematic of an implementation of the processor 60 that may include at least one instance of a finite state machine 170 and/or at least one instance of a computer 172 accessibly coupled 174 via a buss to a computer readable memory 176 containing a program system 178.

The processor 60 may be coupled 62 to at least one of the following components shown in FIG. 8: the first amplifier 110, the second amplifier 112, the differential amplifier 124, the first threshold comparator 122, the second threshold comparator 126 and/or the third threshold comparator 129.

Various configuration parameters of these components of the integrated circuit 120 may be initialized or altered by the processor 60. The first amplifier gain 136 may be used to configure the first amplifier 110. The second amplifier gain 138 may configure the second amplifier 112. The differential amplifier gain 140 may configure the differential amplifier 124. The first threshold comparator parameters 142 may configure the first threshold comparator 122. The second threshold comparator parameters may configure the second threshold comparator 126. And the third threshold comparator parameters may configure the third threshold comparator 129. Any of these threshold comparator parameters 142, 146 and/or 148 may include a high threshold parameter 143 and/or a low threshold parameter.

As used herein, a computer 172 may include at least one data processor and at least one instruction processor, with each data processor instructed by at least one instruction processor through the access 174 of program steps of the program system 178 residing in the computer readable memory 176.

As used herein, a finite state machine 170 includes at least one input, maintains at least one state based upon at least one of the inputs and generates at least one output based upon the value of at least one of the inputs and/or based upon the value of at least one of the states.

Some of the following figures show flowcharts of at least one embodiment of the method, which may include arrows signifying a flow of control, and sometimes data, supporting various implementations of the invention's operations. These include a program operation, or program thread, executing upon a computer 172, and/or a state transition in a finite state machine 170. The operation of starting a flowchart refers entering a subroutine or a macro instruction sequence in the computer, and/or directing a state transition in the finite state machine, possibly while pushing a return state. The operation of termination in a flowchart refers completion of those operations, which may result in a subroutine return in the computer, and/or popping of a previously stored state in the finite state machine. The operation of terminating a flowchart is denoted by an oval with the word “Exit” in it.

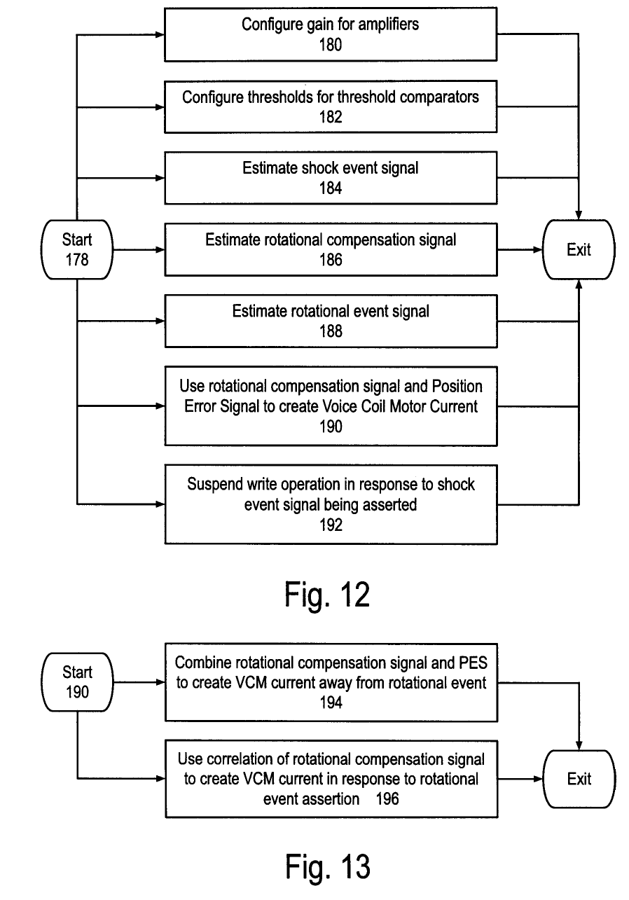

FIG. 12 shows a flowchart of the program system 178 of FIG. 11 including at least one of program steps configuring the amplifiers 110, 112, and/or 124, configuring the threshold comparators 122, 126 and/or 129, estimating the shock event signal 132, the rotational compensation signal 130 and/or the rotational event signal 134, using the rotational compensation signal and Position Error Signal (PES) 154 to create the voice coil motor current 152 and/or suspending write operations in response to the shock event signal being asserted.

In greater detail, the program system 178 may include at least one of the following program steps: Program step 180 supports configuring at least one of the first amplifier 110, the second amplifier 112 and/or differential amplifier 124, which may include setting their gains. Program step 182 supports configuring the thresholds 143 and/or 144 of at least one of the threshold comparators 122, 126 and/or 129. Program step 184 supports estimating the shock event signal 132. Program step 186 supports estimating the rotational compensation signal 130. Program step 188 supports estimating the rotational event signal, which may either be implemented as shown in FIG. 8 or through digital determination of whether the rotational compensation signal is outside the third high threshold and the third low threshold. Program step 190 supports using the rotational compensation signal and the position error signal 154 to create the voice coil motor current 152. And program step 192 supports suspending write operations in response to the shock event signal being asserted.

FIG. 13 shows a flowchart of some of the details of the program step 190 using the rotational compensation signal 130 and Position Error Signal 154 to create the voice coil motor current 152. Program step 194 supports combining the rotational compensation signal and the position error signal (PES) to create the voice coil motor current signal away from a rotational event. And program step 196 supports using a correlation of the rotational compensation signal to create the voice coil motor current in response to the rotational event.

The preceding embodiments provide examples of the invention, and are not meant to constrain the scope of the following claims.

What is claimed is:

1. A hard disk drive, comprising:
a disk base; and
a piezoelectric group consisting of the members of a first piezoelectric device mounted in parallel to said disk base and a second piezoelectric device mounted at an angle Phi to said disk base;
a voice coil motor mounted by an actuator pivot to said disk base to position at least one slider over a track on said rotating disk surface; and
a circuit board mounted on said disk base and including
a processor configured to communicate with said voice coil motor to direct the positioning of said slider over said rotating disk surface and
an integrated circuit electrically coupled to said first piezoelectric device and to said second piezoelectric device to generate a rotational compensation signal and a shock event signal, both reported to said processor to support directing the positioning and operation of said slider and said voice coil motor.

2. The hard disk drive of claim 1, wherein circuit board further includes said first piezoelectric device.

3. The hard disk drive of claim 1, wherein circuit board further includes said second piezoelectric device.

4. The hard disk drive of claim 1, wherein said integrated circuit includes said processor.

5. The hard disk drive of claim 1, wherein said integrated circuit further generates a rotational event signal reported to said processor to further support said positioning and said operation of said slider and said voice coil motor.

6. A circuit board configured to mount on a disk base of a hard disk drive, comprising:
a processor configured to communicate with a voice coil motor to direct the positioning of at least one slider over at least one rotating disk surface in said hard disk drive; and
an integrated circuit configured to electrically couple to the members of a piezoelectric ground to generate a rotational compensation signal and a shock event signal, both reported to said processor to support directing the positioning and operation of said slider and said voice coil motor;
wherein said piezoelectric group consists of the members of a first piezoelectric device mounted in parallel to said disk base and a second piezoelectric device mounted at an angle Phi to said disk base.

7. The circuit board of claim 6, further includes said first piezoelectric device.

8. The circuit board of claim 6, further includes said second piezoelectric device.

9. The circuit board of claim 6, wherein said integrated circuit includes said processor.

10. The circuit board of claim 6, wherein said integrated circuit further generates a rotational event signal reported to said processor to further support said positioning and said operation of said slider and said voice coil motor.

11. An integrated circuit, comprising:
electrical couplings to the members of a piezoelectric group to generate a rotational compensation signal and a shock event signal, both reported to a processor to support directing the positioning and operation of a slider and a voice coil motor included in a hard disk drive,
with said piezoelectric group consisting of the members of
a first piezoelectric device mounted in parallel to said disk base and
a second piezoelectric device mounted at an angle Phi to said disk base.

12. The integrated circuit of claim 11, further includes said first piezoelectric device.

13. The integrated circuit of claim 11, further includes said second piezoelectric device.

14. The integrated circuit of claim 11, wherein said integrated circuit includes said processor.

15. The integrated circuit of claim 11, wherein said integrated circuit further generates a rotational event signal reported to said processor to further support said positioning and said operation of said slider and said voice coil motor.

16. The integrated circuit of claim 11,
wherein said electrical coupling to said first piezoelectric device provides a first signal;
wherein said electrical coupled to said second piezoelectric device provides a second signal;
wherein said shock event signal results from one member of the group consisting of
said first signal being outside a first high threshold and a first low threshold and
said second signal being outside a second high threshold; and
wherein said rotational compensation signal results from a difference between said first signal and said second signal.

17. The integrated circuit of claim 16, further comprising:
a first threshold comparator receiving said first signal to assert a first threshold detection signal in response to said first signal being outside said first high threshold and said first low threshold; and
a second threshold comparator receiving said second signal to assert a second threshold detection signal in response to said second signal being outside said second high threshold and said second low threshold; and
a differential amplifier receiving said first signal and said second signal to create said rotational compensation signal in response to said difference of said first signal and said second signal.

18. The integrated circuit of claim 17, further comprising:
a third threshold comparator receiving said rotational compensation signal to create a rotational event signal in response to said rotational compensation signal being outside third high threshold and said third low threshold.

19. The integrated circuit of claim 18, further comprising:
a first amplifier configured to couple to at least one terminal of said first piezoelectric device to create said first signal; and
a second amplifier configured to couple to at least one terminal of said second piezoelectric device to create said second signal.

20. The integrated circuit of 19, wherein said processor controls at least one parameter configuring at least one member of the group consisting of: said first amplifier, said second amplifier, said differential amplifier, said first threshold comparator, said second threshold comparator, and said third threshold comparator.
